(19) United States
(12) Patent Application Publication
(10) Pub. No.: US 2013/0009657 A1
(43) Pub. Date: Jan. 10, 2013

(54) DETECTION DEVICE

(75) Inventors: YUN-WEN SU, Tu-Cheng (TW); CHI-MIN WANG, Tu-Cheng (TW)

(73) Assignee: HON HAI PRECISION INDUSTRY CO., LTD., Tu-Cheng (TW)

(21) Appl. No.: 13/337,066

(22) Filed: Dec. 24, 2011

(30) Foreign Application Priority Data
Jul. 4, 2011 (TW) 100123564

(51) Int. Cl. G01R 1/067

(52) U.S. Cl. 324/755.01

(57) ABSTRACT

A detection device includes a first rod including a first contact pad, a second rod including a second contact pad, an adjusting rod fixed to the first rod, and a threaded rod fixed to the second rod, the threaded rod being screwed on the adjusting rod. The adjusting rod screws relative to the threaded rod, which causes the distance between the first contact pad and the second contact pad to be adjusted.

### BACKGROUND

1. Technical Field

This disclosure relates to detection devices, particularly to a detection device for detecting components of a circuit board.

2. Description of Related Art

When inputting voltage to the two ends of a component of a circuit board to measure the voltage between the two ends of the component, a soldering iron may be used to solder two wires to the two ends of the component. However, this method is not efficient. Additionally, if the soldering technique is not good, the circuit board may be short circuited, damaging the circuit board.

Therefore, there is a room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary detection device. Wherever possible, the same reference numbers are used throughout the drawings to refer to the same or like elements of an embodiment.

FIG. 1 is a schematic view of an exemplary embodiment of a detection device in a first state.

FIG. 2 is an exploded view of the detection device of FIG. 1.

FIG. 3 is another schematic view of the detection device of FIG. 1 in a second state.

### DETAILED DESCRIPTION

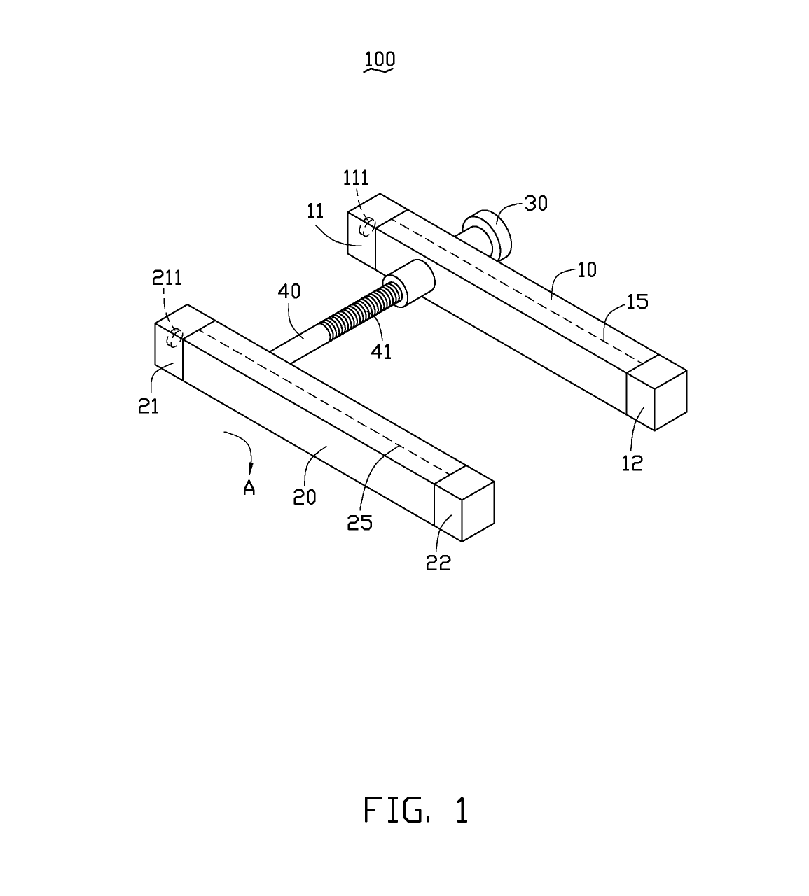

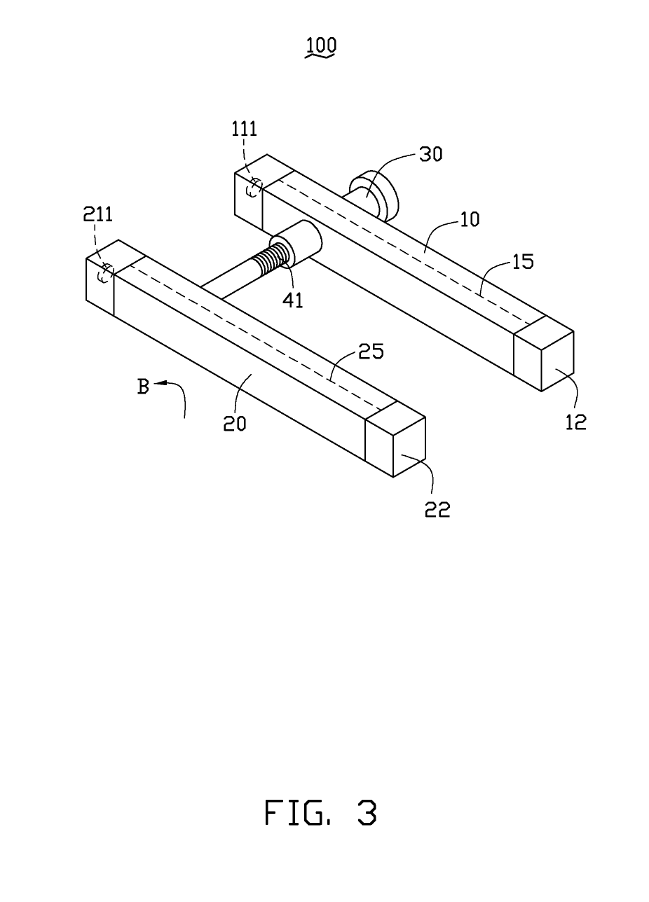

Referring to FIG. 1, an exemplary embodiment of a detection device 100 includes a first rod 10, a second rod 20 parallel to the first rod 10, an adjusting rod 30 and a threaded rod 40. The adjusting rod 30 is mounted on the first rod 10, the threaded rod 40 is mounted on the second rod 20 and screwed onto the adjusting rod 30. The adjusting rod 30 may be rotated relative to the threaded rod 40, causing the first rod 10 to move towards or away from the second rod 20 between a first state shown in FIG. 1 and a second state shown in FIG. 3.

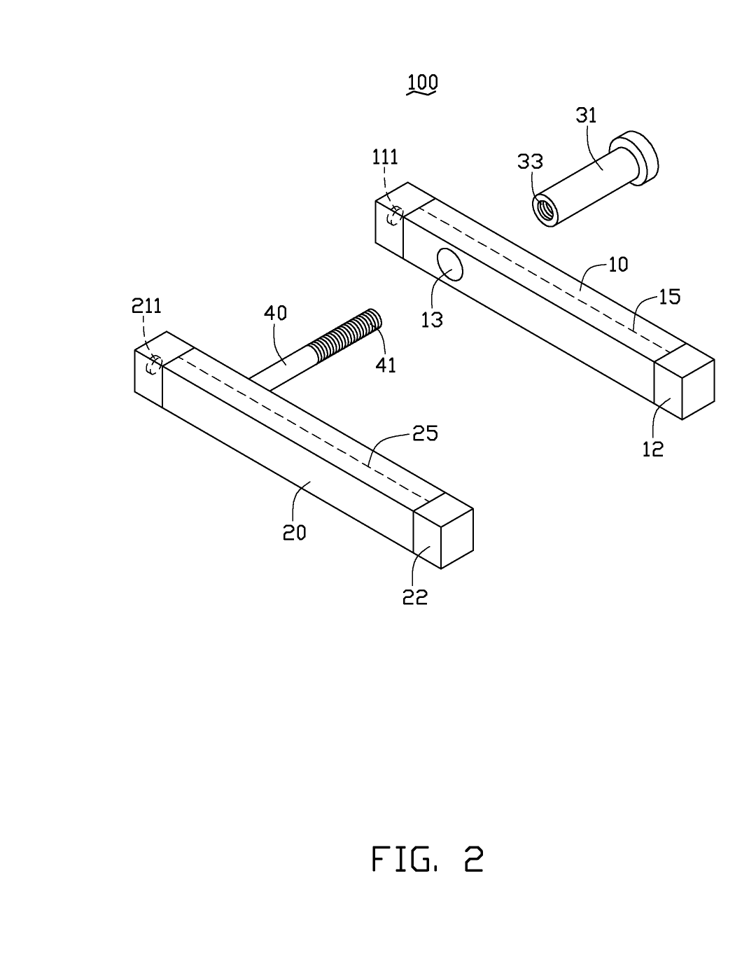

Referring to FIG. 2, the body of the first rod 10 is insulated. The first rod 10 includes a first connector 11 fixed at one end of the first rod 10, a first contact pad 12 fixed at the other end of the first rod 10, and a first guiding wire 15 electrically connecting the first connector 11 with the first contact pad 12. The first rod 10 further defines an opening 13 adjacent to the first connector 11. The first connector 11 and the first contact pad 12 are both made of metal. The first connector 11 defines a first insertion hole 111, such as an insertion hole for electrically connecting to a positive pole of a detecting instrument.

Referring to FIG. 2, the body of the second rod 20 is insulated. The second rod 20 includes a second connector 21 fixed at one end of the second rod 20, a second contact pad 22 fixed at the other end of the second rod 20, and a second guiding wire 25 electrically connecting the second connector 21 with the second contact pad 22. The second connector 21 and the second contact pad 22 are both made of metal. The second connector 21 defines a second insertion hole 211, such as an insertion hole for electrically connecting to a negative pole of the detecting instrument.

The adjusting rod 30 is made of non-conductive material(s), and includes a main body 31 and a threaded hole 33. The main body 31 is a stepped cylinder. The threaded hole 33 is defined in the main body 31. The main body 31 is fixed in the opening 13 so the adjusting rod 30 is rotatably located in the first rod 10.

The threaded rod 40 is fixed to the second rod 20, and includes a threaded portion 41 which may be screwed into the threaded hole 33 so the threaded rod 40 is screwed onto the adjusting rod 30. When the threaded portion 41 is rotated further into or out of the threaded hole 33, the distance between the first rod 10 and the second rod 20 changes.

Referring to FIGS. 1 and 3, if the distance between the first rod 10 and the second rod 20 in the first state is too big for a first component (e.g., a capacitor), the second rod 20 can be rotated around the threaded rod 40 in a first direction (that of arrow A) to drive the threaded rod 40 further into the threaded hole 33. Thus, the first rod 10 moves toward the second rod 2 to reduce the distance between the first rod 10 and the second rod 20 until the distance between the first contact pad 12 and the second contact pad 22 is adapted to the first component, such as in the second state (of FIG. 3). If the distance between the first rod 10 and the second rod 20 in the second state is too small for a second component (e.g., an inductor), the second rod 20 can be rotated around the threaded rod 40 in a second direction (that of arrow B) opposite to the first direction, to screw the rod 40 out of the threaded hole 33. Thus, the first rod 10 moves away from the second rod 20 to increase the distance between the first rod 10 and the second rod 20 until the distance between the first contact pad 12 and the second contact pad 22 is adapted to the second component, such as into the first state (of FIG. 1). Thus, the distance between the first rod 10 and the second rod 20 can be adjusted by the rotation of the threaded rod 40, to adapt to components (e.g., capacitors, inductors) having different sizes. Thus, the utilization rate of the detection device 100 is increased. Additionally, the detection device 100 has no need of a soldering iron to solder the contact pads 12, 22 to the components of a circuit board, thereby preventing the possibility of any short circuit of the circuit board and consequent damage.

It is to be further understood that even though numerous characteristics and advantages of the exemplary embodiments have been set forth in the foregoing description, together with details of structures and functions of various embodiments, the disclosure is illustrative only, and changes may be made in detail, especially in the matters of shape, size, and arrangement of parts within the principles of the exemplary invention to the full extent indicated by the broad general meaning of the terms in which the appended claims are expressed.

What is claimed is:

1. A detection device comprising:
a first rod including a first contact pad;
a second rod including a second contact pad;
an adjusting rod fixed to the first rod; and
a threaded rod fixed to the second rod, the threaded rod being screwed on the adjusting rod;
wherein the adjusting rod screws relative to the threaded rod, which causes the first rod to move toward or away from the second rod between a first state and a second state so that a distance between the first contact pad and the second contact pad is adjusted.

2. The detection device of claim 1, wherein the first rod defines an opening, in which the adjusting rod is fixed.

3. The detection device of claim 2, wherein the adjusting rod defines a threaded hole, the threaded rod comprises a threaded portion, the threaded portion is screwed in the threaded hole so the threaded rod is screwed on the adjusting rod.

4. The detection device of claim 3, wherein the first rod further comprises a first connector, the first connector and the first contact pad are respectively fixed at opposite ends of the first rod.

5. The detection device of claim 4, wherein the first rod further comprises a first guiding wire electrically connecting the first connector with the first contact pad.

6. The detection device of claim 3, wherein the second rod further comprises a second connector, the second connector and the second contact pad are respectively fixed at opposite ends of the second rod.

7. The detection device of claim 6, wherein the second rod further comprises a second guiding wire electrically connecting the second connector with the second contact pad.

8. A detection device comprising:
a first rod including a first contact pad;
a second rod parallel to the first rod, the second rod including a second contact pad corresponding to the first contact pad in location;
an adjusting rod fixed to the first rod; and
a threaded rod fixed to the second rod, the threaded rod being screwed on the adjusting rod;
wherein when the adjusting rod screws relative to the threaded rod, the distance between the first rod and the second rod is adjusted.

9. The detection device of claim 8, wherein the first rod defines an opening, in which the adjusting rod is fixed.

10. The detection device of claim 9, wherein the adjusting rod defines a threaded hole, the threaded rod comprises a threaded portion, the threaded portion is screwed in the threaded hole so the threaded rod is screwed on the adjusting rod.

11. The detection device of claim 10, wherein the first rod further comprises a first connector, the first connector and the first contact pad are respectively fixed at opposite ends of the first rod.

12. The detection device of claim 11, wherein the first rod further comprises a first guiding wire electrically connecting the first connector with the first contact pad.

13. The detection device of claim 10, wherein the second rod further comprises a second connector the second connector and the second contact pad are respectively fixed at opposite ends of the second rod.

14. The detection device of claim 13, wherein the second rod further comprises a second guiding wire electrically connecting the second connector with the second contact pad.
